(19) United States
(12) Patent Application Publication
(10) Pub. No.: US 2026/0140338 A1
(43) Pub. Date: May 21, 2026

(54) Integrated, High-Speed Optical Transceiver

(71) Applicant: Tectus Corporation, Cupertino, CA (US)

(72) Inventors: Michael West Wiemer, San Jose, CA (US); Paul Scott Martin, Palo Alto, CA (US); Brian Elliot Lemoff, Morgan Hill, CA (US)

(21) Appl. No.: 19/447,710

(22) Filed: Jan. 13, 2026

Related U.S. Application Data
(63) Continuation of application No. PCT/US2025/044032, filed on Aug. 28, 2025.
(60) Provisional application No. 63/693,666, filed on Sep. 11, 2024.

(51) Int. Cl. G02B 6/42; H10F 77/122; H10H 20/812; H10H 20/825; H10W 80/00; H10W 90/00; H10W 90/20

(52) U.S. Cl. CPC G02B 6/4245; G02B 6/4206; G02B 6/4274; G02B 6/4298; H10W 80/314; H10W 80/327; H10W 90/297; H10W 90/792; H10F 77/122; H10H 20/812; H10H 20/825

(57) ABSTRACT

An advanced integrated optical transceiver enables super high-speed communication between chips such as GPUs and HBM. Designs for such a transceiver may be based on an array of GaN micro-LEDs and an array of Si photodetectors (PDs) which are hybrid bonded (i.e. via “direct bond interconnect”) to a CMOS chip. Hybrid bonding makes the integrated optical transceiver very small and highly reliable.

### CROSS-REFERENCE TO RELATED APPLICATION(S)

This application claims priority under 35 U.S.C. § 119(e) to U.S. Provisional Patent Application Ser. No. 63/693,666, “Integrated, High-Speed Optical Transceiver,” filed Sept 11, 2024. The subject matter of all of the foregoing is incorporated herein by reference in its entirety.

### BACKGROUND

### 1. Technical Field

This disclosure relates generally to optical transmitters, receivers and transceivers.

### 2. Description of Related Art

Finite communication speeds between data sources and sinks limit modern computing performance. In AI data centers, for example, data transfer rates between graphics processing units (GPUs) and high-bandwidth memory (HBM) are a bottleneck. Optical chip-to-chip interconnects offer a potential solution. Optical interconnects have significant advantages over electrical interconnects including higher bandwidth, no need for electronic channel equalization, and lighter weight.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIG. 1A shows a cross-section of an integrated optical transceiver for chip-to-chip communication.

FIG. 1B is a block diagram of the integrated optical transceiver of FIG. 1A.

FIG. 2 shows an optical fiber data transmission system for chip-to-chip communication.

FIGS. 3A-3E show fabrication of an integrated optical transceiver.

FIG. 4 shows a cross-section of another integrated optical transceiver with a three-layer stack.

FIG. 5 shows a cross-section of an integrated optical transceiver with a two-layer stack.

The figures are schematic, cross-sectional views and are not drawn to scale. The thicknesses of layers may be grossly exaggerated and not scaled consistently.

### DETAILED DESCRIPTION OF THE PREFERRED EMBODIMENTS

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Optical interconnects, such as those described in U.S. Pat. No. 11,764,878 (“LED chip-to-chip vertically launched optical communications with optical fiber”) and U.S. Pat. No. 11,515,356 (“Chip-scale optical interconnect using microLEDs”), may be based on multi-chip modules in packages that are connected to a circuit board by solder balls. The packages include chips and interposers. Some of the chips in a package may be optical transceivers with LEDs (die from a separate wafer) mounted on them. The optical transceiver chips communicate with other chips in the multi-chip module via the interposers. However, the use of multi-chip modules, interposers and other similar packages results in longer wire lengths and higher capacitances, which limit the speed of these transceivers. What is needed are ever more robust and reliable optical transceivers capable of transporting data at higher rates between chips.

Integrated optical transceivers described herein can enable super high-speed communication between chips such as GPUs and HBM. Designs for such a transceiver may be based on an array of GaN micro-LEDs and an array of Si photodetectors (PDs) which are hybrid bonded (i.e. via “direct bond interconnect”) to a CMOS chip. Wafer-to-wafer hybrid bonding makes the integrated optical transceiver very small and highly reliable. Hybrid-bonded connections between wafers also have low capacitance and low power dissipation at high frequencies. The capacitance of chip-to-chip connections may be in the range of a few pF, while the capacitance of within-chip connections in a hybrid bonded chip may be in the range of 1-10 fF. In addition, heat is more easily conducted away from a solid, continuous, hybrid-bonded structure compared to structures having gaps between chips. Hybrid bonding also takes advantage of precise alignment tolerances associated with advanced semiconductor fab facilities—better than may be achieved with chip-to-chip bonding.

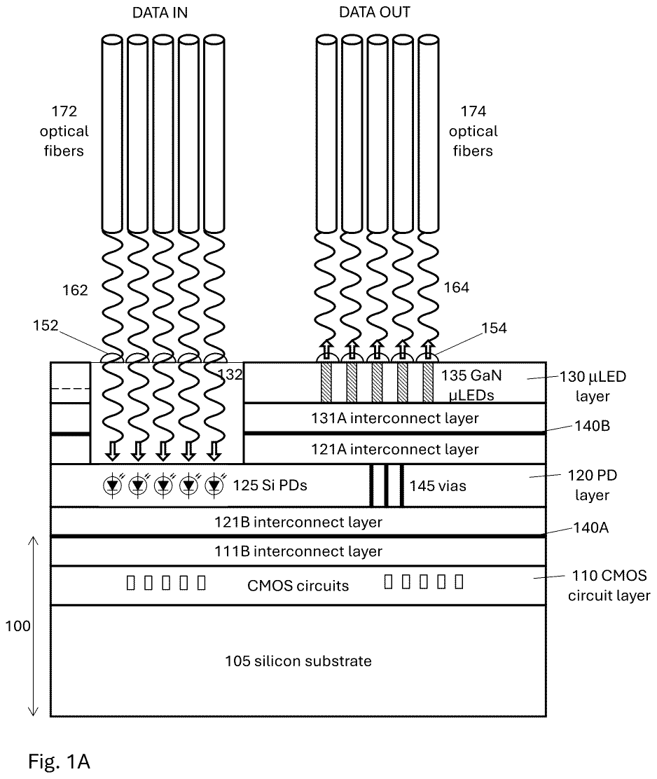

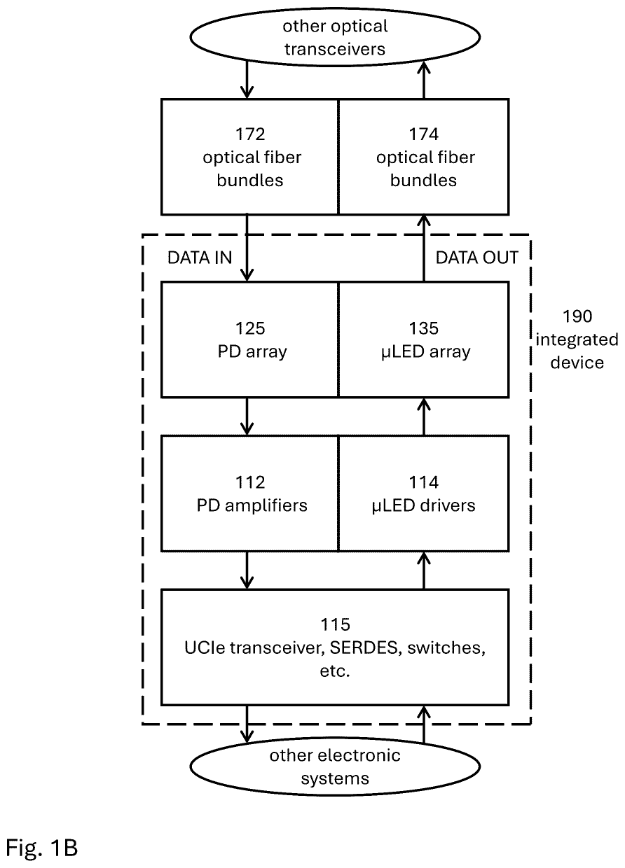

FIG. 1A shows a cross-section of an integrated optical transceiver for chip-to-chip communication, in accordance with some embodiments of the present disclosure. The transceiver includes a CMOS chip 100, which includes a CMOS circuit layer 110 on a silicon substrate 105. The transceiver also includes a photodetector (PD) layer 120 and a micro-LED (light emitting diode) layer 130. The PD layer 120 includes an array of photodetectors 125. The micro-LED layer 130 includes an array of micro-LEDs 135. In this example, the PD layer 120 is a silicon layer with silicon photodiodes and the micro-LED layer 130 is a GaN layer with GaN quantum well micro-LEDs. Micro-LEDs may be less than 200 μm wide, or less than 100 μm wide, or even less than 50 μm wide. The CMOS circuit layer 110 includes circuits, such as driver circuits for the micro-LEDs and amplifiers for the PDs.

The integrated optical transceiver includes hybrid bonding 140A, B between the different layers 110, 120, 130. In hybrid bonding, an oxide layer on one layer 110, 120, 130 is bonded to an oxide layer on the other layer 110, 120, 130. Metal plugs in the two layers are aligned with one another and slightly recessed, by 1˜2 nm for example. Hybrid bonding may be wafer-to-wafer or die-to-wafer. When the dies and/or wafers containing the two layers, adhered by oxide, are heated, the metal plugs expand and fuse together to make electrical connections. Thus, the hybrid bonding 140A, B provides electrical connections between the layers and also mechanically attaches the different layers. More specifically, the hybrid bonding 140A, B provides electrical connections between corresponding interconnect layers 111B-121B and 121A-131A within each of the layers 110, 120, 130.

This example uses a stack of three layers: micro-LED layer 130, PD layer 120 and CMOS circuit layer 110 from top to bottom. The top layer (micro-LED layer 130) is hybrid bonded 140B to the middle layer (PD layer 120), which is hybrid bonded 140A to the bottom layer (CMOS circuit layer 110). The silicon photodiodes 125 are electrically connected to CMOS circuitry (e.g., transimpedance amplifiers) by the hybrid bonding 140A. The micro-LEDs 135 are electrically connected to CMOS circuitry (e.g., drivers) by the hybrid bondings 140A, 140B and vias 145 through the middle layer 120. The vias 145 may be copper damascene structures.

In FIG. 1A, five GaN micro-LEDs 135 are shown, but arrays containing tens, hundreds, thousands or more micro-LEDs may be fabricated. Each micro-LED may have a maximum width of about 0.6 μm to about 5 μm, and the array of micro-LEDs may have a pitch of 50 μm or less. Microlenses 154 (or other optical coupling devices) may couple light from the micro-LEDs 135 into multi-mode optical fibers 174. Each microlens may have a diameter of about 2 μm to about 50 μm. Each multimode optical fiber may have a core diameter of about 10 μm to about 50 μm. The diameter of the fiber cores may be greater than the diameter of the microlenses. The minimum spatial repetition interval, or pitch, of micro-LEDs in the array may be less than, equal to, or greater than the pitch of the multimode optical fibers.

Similar sizes and numbers may apply to the array of PDs 125, particularly if the data rates are similar in the transmit and receive directions. The PDs may be avalanche photodiode detectors or other types of optical detectors.

The optical transceiver provides a data transmit path (DATA OUT) and a data receive path (DATA IN) as also shown in the block diagram of FIG. 1B. For the receive path, the array of Si PDs 125 receives data-encoded light 162 from a bundle of multimode optical fibers 172. Microlenses 152 may be used to couple the light 162 from the optical fibers 172 to the PDs 125, and an aperture 132 in the top micro-LED layer 130 allows propagation of light through the top layer. The aperture 132 may be filled with a thin, transparent fill layer, e.g. of SiO₂, which covers the PDs and planarizes the surface of the structure. The PDs 125 convert the incoming light from optical to electrical form. The CMOS circuit layer 110 contains electronic circuits 112, 115 which receive and demodulate the electrical signals detected by the PDs to recover the digital data encoded on light 162.

For the transmit path, the array of GaN micro-LEDs 135 sends data-encoded light 164 to a bundle of multimode optical fibers 174. Microlenses 154 may couple the light from the micro-LEDs 135 to the optical fibers 174. The CMOS circuit layer 110 contains electronic circuits 114, 115 which drive and modulate the micro-LEDs 135 according to digital data received by the transceiver. The CMOS circuit layer 110 may also include a feedback path from the receive path to the transmit path, either for the relay of data from the receive path to the transmit path or for control/processing of the data paths (e.g., equalization).

The components in the dashed box of FIG. 1B may be implemented as an integrated device 190, such as shown in FIG. 1A.

The CMOS chip 100 itself may be a data source providing DATA OUT and/or a data sink consuming DATA IN. Examples include graphics processing units (GPUs) and high-bandwidth memory (HBM). If not, it may be connected to other digital sources and sinks via a high speed digital interface, such as UCIe (Universal Chiplet Interconnect Express), PCIe (Peripheral Component Interconnect Express) or CXL (Compute Express Link). Other types of SERDES (serializer/deserializer) interfaces may be used. The digital interface receives digital data from other chips, which the transmit path and micro-LEDs transmit optically as DATA OUT. It transmits digital data to the other chips, which the receive path and PDs recover from the optical DATA IN.

The use of hybrid-bonded structures described here allow high-speed electronic chips to have optical transmitters and receivers integrated without resorting to interposers. Hybrid-bonded connections between wafers are short and have low capacitance, which leads to low power dissipation at high frequencies. The three-layer stack shown in FIG. 1A may have a maximum height of 20 μm or less from the top of the CMOS circuit layer 110 to the top of the uppermost layer (micro-LED layer 130) in this example. As a result, the electrical connections are shorter with lower capacitance.

In addition, heat is more easily conducted away from a solid, continuous, hybrid-bonded structure compared to structures having gaps between chips. Hybrid bonding also takes advantage of precise alignment tolerances associated with advanced semiconductor fab facilities—better than may be achieved with chip-to-chip bonding. Alignment to the integrated micro-LEDs and photodetectors described here may be more precise than to discrete components separately bonded to a wafer.

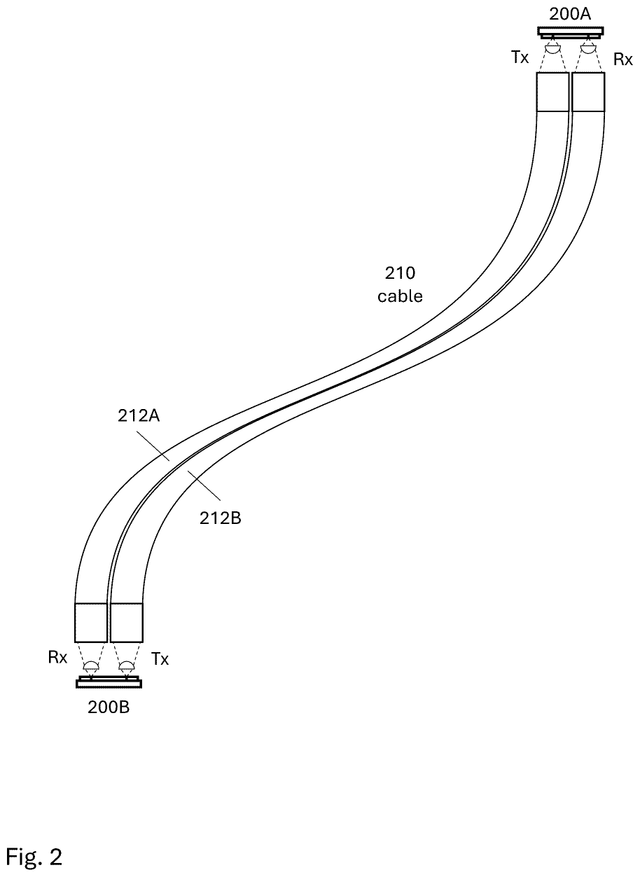

FIG. 2 shows an optical fiber data transmission system using the optical transceivers of FIG. 1A. Each optical transceiver 200A, B is divided into a transmitter (TX) and receiver (RX). A cable 210 transports light between the two transceivers. This example shows a single cable 210 which includes two bundles 212A, B of multimode fibers. One bundle 212A receives data-encoded light from the transmitter of transceiver 200A and transports the light to the receiver of transceiver 200B. The other bundle 212B receives data-encoded light from the transmitter of transceiver 200B and transports the light to the receiver of transceiver 200A. The multimode optical fibers in the cable may be step-index or graded index fibers. The cable 210 may be about 1 cm to about 50 m long. The bandwidth of the fiber may be limited by modal dispersion, but for lengths up to about 50 m the bandwidth may exceed several GHz per fiber. Different applications may use different bandwidths per fiber and aggregate bandwidths for the fiber bundle.

Since each bundle contains multiple fibers, the aggregate data rate of this system may be at least 100 Gbps (gigabits per second) in each direction. In other applications, the aggregate data rate may be 10 Tbps, 100 Tbps or more. The fibers within each bundle may be arranged in different formats. Hexagonally packed fibers provide good space utilization and easy assembly. The micro-LEDs and PDs may also be arranged in hexagonal arrays.

In each transceiver 200A, B, the micro-LED array and PD array may be adjacent to each other, so that a single mechanical connection may be used to connect each end of cable 210 (and both fiber bundles) to one of the transceivers 200. In other cases, separate mechanical connections may be used for different fiber bundles.

Other cable arrangements may be used. For example, separate cables may be used for each direction of data transport. In addition, the data transport does not have to be bidirectional. It may be unidirectional, in which case each chip 200A, B could be either a transmitter or receiver but not necessarily both. The data transport may not be a point to point connection between two transceivers. Data may be transmitted from chip A to chip B to chip C, etc. Alternatively, data may be transmitted from chip A to chips B and C, either as two separate connections or as a broadcast connection.

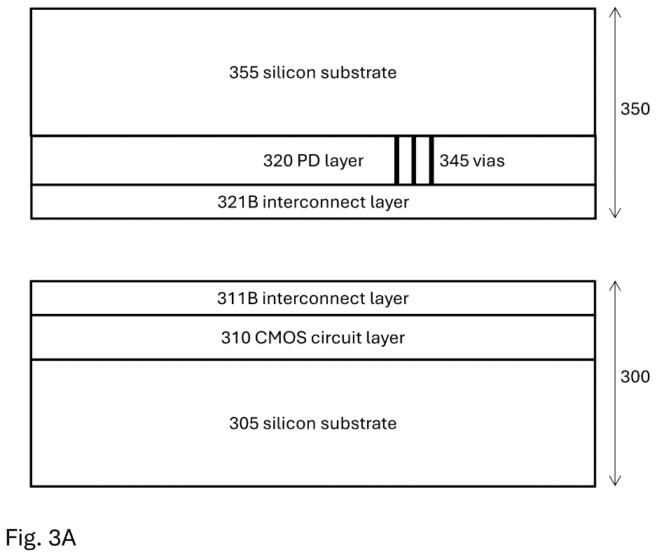

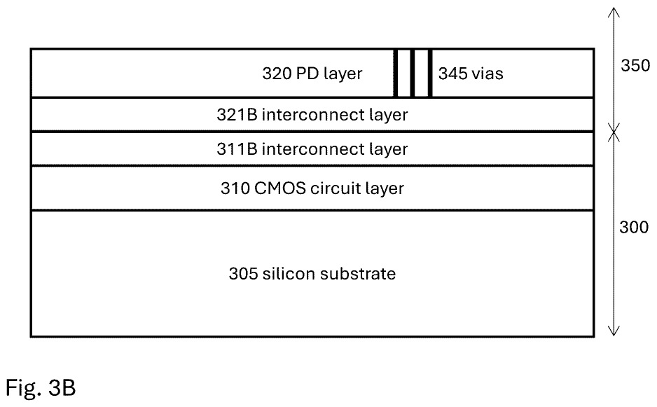

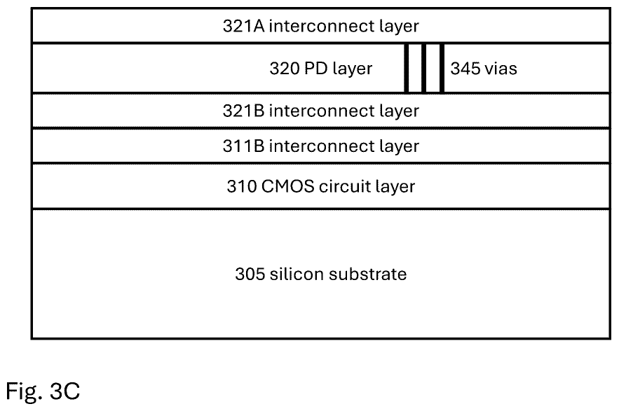

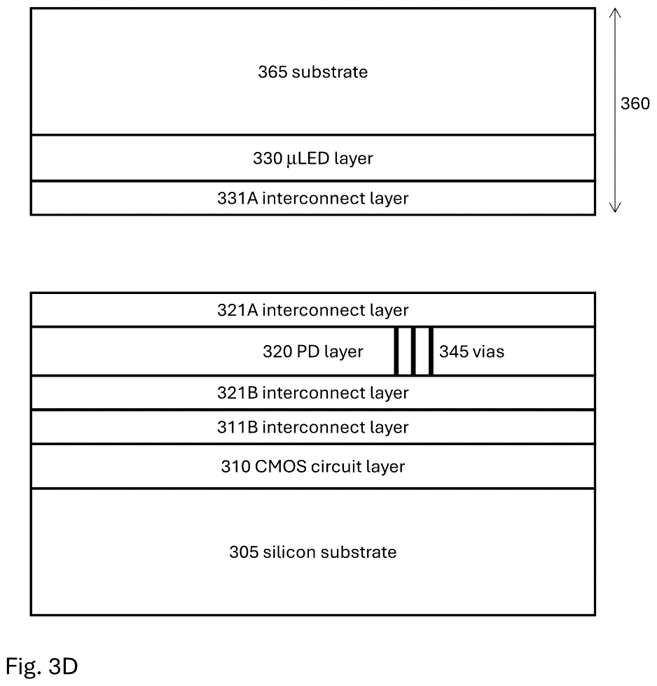

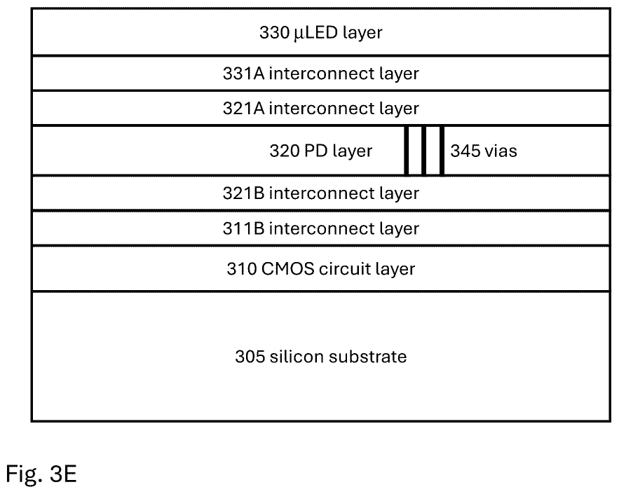

FIGS. 3A-3E show fabrication of the integrated optical transceiver of FIG. 1A. Briefly, a wafer containing an array of Si PDs may be hybrid bonded to a CMOS wafer containing high bandwidth electronics, such as a GPU wafer or an HBM wafer. The other surface of the Si PD wafer, i.e. the one which is not bonded to the CMOS wafer, may be polished, e.g. by chemical-mechanical polishing (CMP). This leaves a suitable oxide surface with Cu plugs ready for a second hybrid bonding step in which the GaN micro-LEDs are attached.

In the GaN layer, individual micro-LEDs are addressable in the final device. Similarly, in the Si photodetector layer, individual photodetectors are addressable. The creation of individually addressable micro-LEDs or photodetectors may be via doping or filling with SiO₂ or other materials between devices, or by having a space or empty groove between devices. An array of micro-LEDs or photodetectors may cover only a small fraction of the area of a high-speed chip. In that case, most of the area of the GaN micro-LED “layer” or the Si photodetector “layer” may in fact be SiO₂ and/or signal routing layers. For clarity, layers rather than patterned individual devices are shown in FIGS. 3A-3E.

In many processes, the individual components are defined before hybrid bonding. However, it is also possible to hybrid bond first and define the micro-LEDs or PDs afterward, or a combination of before and after. Examples of hybrid bonding are described in U.S. Pat. No. 11,476,387 (“Ultra-dense array of LEDs with half cavities and reflective sidewalls, and hybrid bonding methods”) and U.S. Pat. No. 11,973,174 (“LED displays fabricated using hybrid bonding”), both of which are incorporated by reference in their entirety.

FIG. 3A shows a CMOS wafer 300 and a PD wafer 350. The CMOS wafer 300 includes a CMOS circuit layer 310 on underlying silicon substrate 305. The CMOS circuit layer 310 may contain high speed electronic circuits. The CMOS wafer 300 also includes an interconnect layer 311B, which contains metal layers for signal routing. The exposed surface of the interconnect layer 311B is mostly SiO₂ except for some exposed and slightly (by 1-2 nm) dished Cu plugs.

The PD wafer 350 includes a PD layer 320 on a silicon substrate 355. The PD layer 320 includes the Si photodetectors (or their precursors if not yet fabricated into individual photodetectors). It may also include vias 345. At this stage of processing, the vias may be blind holes filled with metal. The vias may be through silicon vias, through oxide vias, or through a combination of materials. The PD wafer 350 may be produced using 300 mm diameter Si wafers. It also includes interconnect layer 321B, which includes metal layers for electrical signal routing and a SiO₂ surface and Cu plugs for hybrid bonding.

In FIG. 3A, the CMOS wafer 300 is hybrid bonded to the PD wafer 350. The SiO₂ surface and corresponding Cu plugs on the two interconnect layers 311B-321B are designed to mate to each other. The interconnect layers 311B-321B of the two wafers are brought together and their SiO₂ surfaces bonded. Afterward, the structure is heated and Cu plugs in each interconnect layer 311B-321B expand and fuse with their counterparts in the other wafer to form electrical connections.

FIG. 3B shows the Si PD wafer 350 bonded to the CMOS wafer 300 after the Si PD wafer has been thinned in preparation for backside illumination of the PDs. This thinning step may be performed by etching, grinding and/or chemical-mechanical polishing (CMP).

FIG. 3C shows the structure of FIG. 3B after another interconnect layer 321A has been formed on the PD layer 320. This process may involve oxide deposition, etching and metal deposition steps to make connections to the vias 345.

FIG. 3D shows the structure of FIG. 3C, plus a GaN-on-substrate wafer 360. The GaN-on-substrate wafer 360 includes a micro-LED layer 330 on a substrate 365. The substrate 365 may be Si, Al₂O₃ or an engineered substrate based on an amorphous ceramic, with a thin (2-10 μm) epitaxial GaN layer 330 grown on it. The micro-LED layer 330 includes GaN micro-LEDs or it may be just GaN epitaxial layers before patterning into individual micro-LEDs. Alternatively, the GaN layers may be grown on engineered surfaces. The GaN layer may contain multiple quantum wells (MQW) which form the active layer of light emitting diodes. The GaN-on-substrate wafer 360 also includes an interconnect layer 331A, which is formed in an oxide layer deposited on the GaN layer, for example during a process in which individual micro-LEDs are defined. The MQW may be located within about 1-2 μm of the interconnect layer 331A, i.e. within the last 1-2 μm of GaN grown on the substrate.

In FIG. 3D, the GaN-on-substrate wafer 360 is hybrid bonded to the PD layer 320 via the interconnect layers 321A-331A.

FIG. 3E shows the structure of FIG. 3D after the substrate 365 of the GaN-on-substrate wafer has been removed and the remaining GaN has been thinned. The substrate 365 may be removed by laser lift-off or grinding and polishing.

The approach shown in FIGS. 3A-3E allows the PD layer 320 and the microLED layer 330 to be based on different material systems. The PD layer may be based on silicon and the micro-LED layer may be based on a III-V materials system, for example.

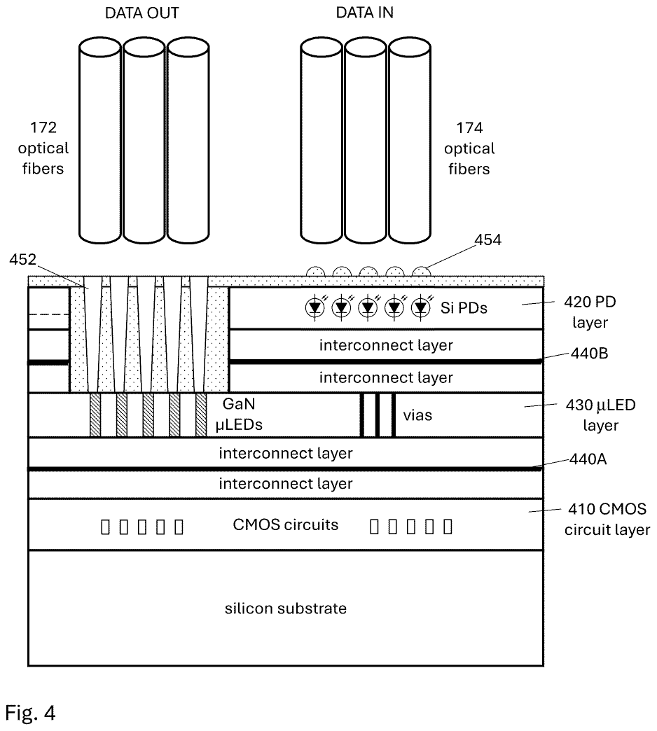

FIG. 4 shows a structure similar to that shown in FIG. 1A. However, in FIG. 4 the GaN micro-LED layer 430 is the middle layer, between the Si PD top layer 420 and the CMOS circuit bottom layer 410. This structure is created by swapping the order of hybrid bonding. First the GaN-on-substrate wafer is hybrid bonded to the CMOS wafer. Next the Si PD wafer is hybrid bonded to the GaN wafer. The window and microlenses over the micro-LEDs is replaced by an array of tapers 452 since more distance is available. Microlenses 454 are used for the PDs. There also is not a one-to-one ratio of optical fibers 172, 174 to micro-LEDs/PDs.

Structures similar to the ones described above may also be formed by chip-to-wafer bonding, in addition to wafer-to-wafer bonding. This may be useful in cases where the areas of the micro-LED layer or the PD layer are much smaller than the area of the CMOS chip. Both the PD layer and the micro-LED layer may be hybrid bonded using wafer-to-wafer bonding. Alternatively, one or both layers may be bonded using chip-to-wafer bonding.

Similar permutations are also possible with respect to patterning individual PDs/micro-LEDs. Both the PD layer and the micro-LED layer may be hybrid bonded first and then patterned into individual devices (PDs and micro-LEDs). Alternatively, one or both layers may be patterned into individual devices before hybrid bonding.

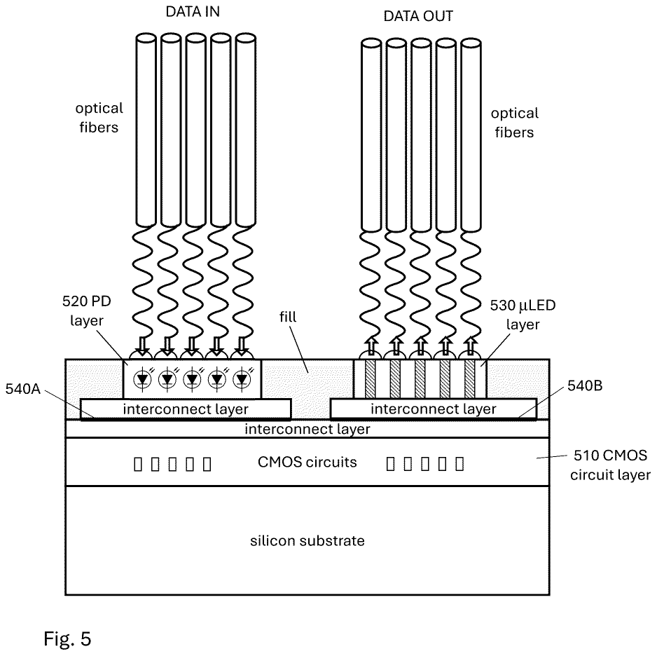

FIG. 5 shows a structure in which both the Si PD layer 520 and the GaN microLED layer 530 are hybrid bonded to the CMOS circuit layer 510 by hybrid bondings 540A and 540B, respectively. This structure can have a flat top surface. The distance to the optical fibers is approximately the same for both PDs and micro-LEDs, which simplifies the optical design for microlenses, lightguide tapers or other optical coupling devices. Another advantage is that electrical connections can be shorter. For example, both the PDs and the micro-LEDs are connected directly to the CMOS circuits, without requiring vias to traverse through intermediate layers. In both the two-layer and three-layer stacks, both the thickness from the top of the PD layer to the top of the CMOS circuit layer and from the top of the micro-LED layer to the top of the CMOS circuit layer may be 20 μm or less, resulting in shorter connections and lower capacitance.

The structure of FIG. 5 may be fabricated by using chip-to-wafer bonding. The wafers containing the PD layer and/or micro-LED layer may be diced into individual dies, and then these are hybrid bonded to the CMOS wafer. Chip-to-wafer bonding can also be used to fabricate any of the three-layer stacks described above.

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

1-25. (canceled)

26. A method for fabricating an optical transceiver comprising:
hybrid bonding a first layer to a CMOS circuit layer of a CMOS chip, the first layer comprising one of a photodetector (PD) layer and a micro-LED (light emitting diode) layer; and
hybrid bonding a second layer to either the first layer or to the CMOS circuit layer, the second layer comprising the other of the PD layer and the micro-LED layer.

27. The method of claim 26 wherein the second layer is hybrid bonded to the first layer.

28. The method of claim 27 further comprising: creating an aperture in the second layer to allow propagation of data-encoded light to or from the first layer.

29. The method of claim 28 further comprising: filling the aperture with a transparent fill to a surface of the second layer.

30. The method of claim 27 further comprising: fabricating vias through the first layer, the vias providing electrical connection between the second layer and the CMOS circuit layer.

31. The method of claim 27 wherein both hybrid bondings are wafer-to-wafer bondings.

32. The method of claim 26 wherein the second layer is hybrid bonded to the CMOS circuit layer.

33. The method of claim 26 wherein the hybrid bonding comprises oxide to oxide bonding with copper plugs.

34. The method of claim 26 wherein the PD layer is on a PD substrate, the microLED layer is on a micro-LED substrate, and the method further comprises:
removing and/or thinning the PD substrate after hybrid bonding the PD layer; and
removing and/or thinning the micro-LED substrate after hybrid bonding the micro-LED layer.

35. The method of claim 26 wherein one of the hybrid bondings is a wafer-to-wafer bonding and the other of the hybrid bondings is a chip-to-wafer bonding.

36. The method of claim 26 wherein both of the hybrid bondings are chip-to-wafer bondings.

37. The method of claim 26 wherein both of the PD layer and the micro-LED layer are patterned into individual PDs and individual micro-LEDs before hybrid bonding.

38. The method of claim 26 wherein both of the PD layer and the micro-LED layer are patterned into individual PDs and individual micro-LEDs after hybrid bonding.

39. The method of claim 26 wherein one of the PD layer and the micro-LED layer is patterned into individual PDs and individual micro-LEDs before hybrid bonding and the other is patterned after hybrid bonding.
